(19) United States
(12) Patent Application Publication
(10) Pub. No.: US 2025/0159901 A1
(43) Pub. Date: May 15, 2025

(54) ELECTRONIC DEVICE

(71) Applicant: Commissariat à l'Énergie Atomique et aux Énergies Alternatives, Paris (FR)

(72) Inventors: Sébastien Kerdiles, Grenoble (FR); Marios Barlas, Grenoble (FR); Laurent Grenouillet, Grenoble (FR); Mathieu Opprecht, Grenoble (FR)

(73) Assignee: Commissariat à l'Énergie Atomique et aux Énergies Alternatives, Paris (FR)

(21) Appl. No.: 18/939,658

(22) Filed: Nov. 7, 2024

(30) Foreign Application Priority Data
Nov. 9, 2023 (FR) 2312188
Nov. 9, 2023 (GR) 20230100929

(51) Int. Cl. H10B 53/30

(52) U.S. Cl. CPC H10B 53/30; H10D 1/692

(57) ABSTRACT

A method of manufacturing an electronic device, the method including: the forming of a support including at least a first insulating layer and conductive tracks; the forming of a second insulating layer; the forming of cavities in the second insulating layer; and the forming of a memory cell in a first location including: the forming of a stack of layers extending over the walls and the bottom of the cavities, the stack including a layer made of a material capable of becoming ferroelectric located between a first conductive layer and a second conductive layer; and the application of a laser to the stack of layers at at least the first location so as to activate ferromagnetic properties of the layer.

This application claims the priority benefit of Greek patent application number GR20230100929 and of French patent application number FR2312188, both filed on Nov. 9, 2023, which are hereby incorporated by reference to the maximum extent allowable by law.

### TECHNICAL FIELD

The present disclosure generally concerns electronic devices and more particularly memory devices.

### PRIOR ART

Ferroelectricity is the property according to which a material has an electrical polarization in the spontaneous state, which polarization can be reversed by the application of an external electric field. The signature of a ferroelectric material is the hysteresis cycle of the polarization according to the applied electric field.

### SUMMARY OF THE INVENTION

An embodiment provides a method of manufacturing an electronic device, the method comprising: the forming of a support comprising at least a first insulating layer having conductive tracks located therein; the forming of a second insulating layer on the support; the forming of cavities in the second insulating layer; and the forming of a memory cell in a first location comprising: the forming of a stack of layers, the stack extending over the walls and the bottom of the cavities, the stack comprising a layer made of material capable of becoming ferroelectric located between a first conductive layer and a second conductive layer, the forming of the stack comprising the forming of the first and second conductive layers and of a dielectric layer between the first and second conductive layers; the application of a laser to the stack of layers at at least the first location so as to activate ferroelectric properties of the layer made of a material capable of becoming ferroelectric; the forming of a layer covering the second conductive layer, said layer being: a protective layer covering the second conductive layer, the step of application of the laser being carried out after the forming of the protective layer; or a third conductive layer covering the second conductive layer, the third conductive layer filling the cavities.

According to an embodiment, the laser is only applied to the first location.

According to an embodiment, the laser is applied to the entire device, portions of the second conductive layer surrounding the first location being protected, during the application of the laser, by a protection mask.

According to an embodiment, during the application of the laser, the dielectric layer is entirely covered by the second conductive layer.

According to an embodiment, the protective layer is transparent to the wavelength of the laser.

According to an embodiment, the second conductive layer has a thickness strictly higher than 1 nm, for example higher than or equal to 3 nm, for example ranging from 3 nm to 20 nm, the second layer being made of a material authorizing the full absorption of the energy of the laser so as to heat the dielectric layer by diffusion.

According to an embodiment, the dielectric layer is heated to a temperature higher than 500° C.

According to an embodiment, the laser is applied in pulses having a duration shorter than 1 μs.

According to an embodiment, the laser has a wavelength shorter than 400 nm.

According to an embodiment, the method comprises the manufacturing of at least one capacitor in a second location, the capacitor comprising the first and second conductive layers and the dielectric layer, and the laser is not applied to the dielectric layer at the second location.

According to an embodiment, the side walls of the cavities are inclined and each form an angle in the range from 0.5° to 5° with a direction orthogonal to the plane of the bottom of the cavities.

According to an embodiment, the layer made of a ferroelectric material is made of hafnium oxide or of HfZrO2.

According to an embodiment, the layer made of a ferroelectric material is made of silicon-doped hafnium oxide, the silicon content being in the range from 0.5% to 5%.

According to an embodiment, the first conductive layer is made of silicon doped titanium nitride.

Another embodiment provides an electronic device comprising: a support comprising at least a first insulating layer having conductive tracks located therein and a second insulating layer comprising cavities; a memory cell comprising a stack of layers, the stack extending over the walls and the bottom of the cavities, the stack comprising a layer made of ferroelectric material located between a first conductive layer and a second conductive layer, the second conductive layer being continuous and entirely metallic; a layer covering the second conductive layer, said layer being: a protective layer; or a third conductive layer, the third conductive layer filling the cavities.

According to an embodiment, the device comprises a capacitor comprising a stack of layers, the stack extending over the walls and the bottom of the cavities, the stack comprising a layer made of material capable of becoming ferroelectric located between a first conductive layer and a second conductive layer, the second conductive layer being continuous and entirely metallic.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1A shows a perspective view of an embodiment of an electronic device;

FIG. 1B shows a cross-section view of an embodiment of the electronic device of FIG. 1A;

FIG. 1C shows a cross-section view of an embodiment of the electronic device of FIG. 1A;

FIG. 2 shows a step of a method of manufacturing the embodiment of FIGS. 1A, 1B, and 1C;

FIG. 3 shows another step of a method of manufacturing the embodiment of FIGS. 1A, 1B, and 1C;

FIG. 4 shows another step of a method of manufacturing the embodiment of FIGS. 1A, 1B, and 1C;

FIG. 5 shows another step of a method of manufacturing the embodiment of FIGS. 1A, 1B, and 1C;

FIG. 6 shows another step of a method of manufacturing the embodiment of FIGS. 1A, 1B, and 1C;

FIG. 7 shows another step of a method of manufacturing the embodiment of FIGS. 1A, 1B, and 1C;

FIG. 8 shows another step of a method of manufacturing the embodiment of FIGS. 1A, 1B, and 1C;

FIG. 9 schematically shows a top view of a device such as the device of FIGS. 1A, 1B, and 1C;

FIG. 10 shows another embodiment of an electronic device; and

FIG. 11 shows another embodiment of an electronic device.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

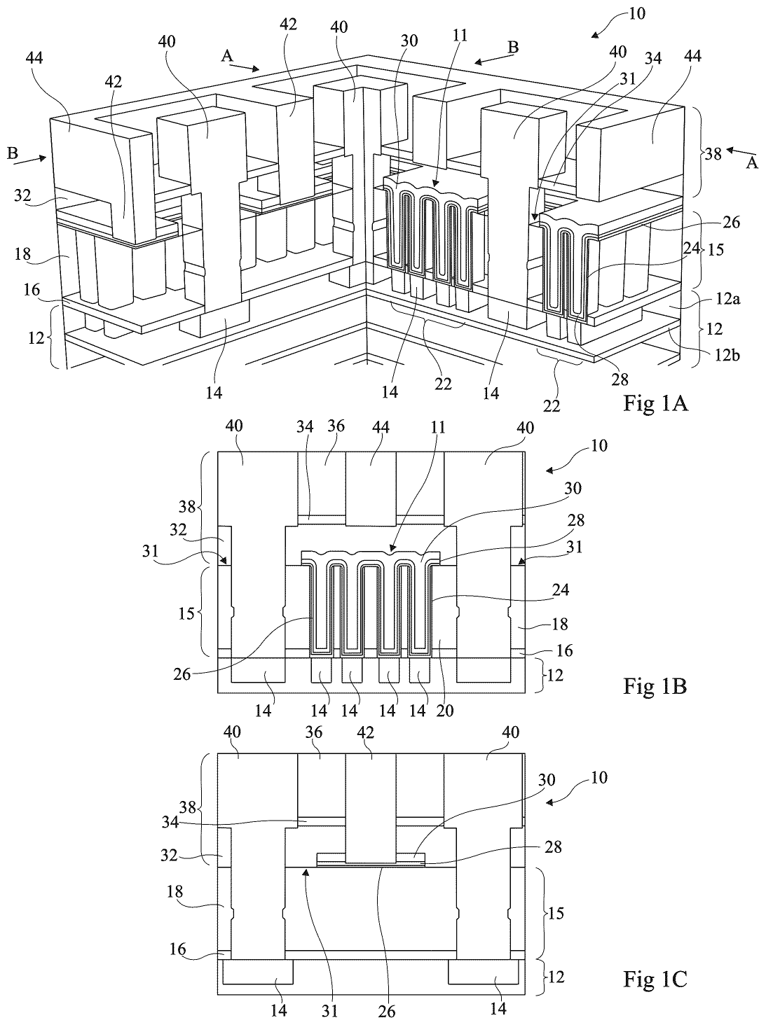

FIGS. 1A, 1B, and 1C show an embodiment of an electronic device 10, comprising at least one memory cell 11, in the example of FIGS. 1A, 1B, and 1C, a single cell 11. More precisely, FIG. 1A shows a perspective view of device 10. FIG. 1B shows a cross-section view of device 10 along a plane A-A. FIG. 1C shows a cross-section view of device 10 along a plane B-B.

Memory cell 11 is a ferroelectric-type cell. In other words, the cell contains a value programmed by an electrical polarization. For example, the device comprises a plurality of memory cells such as cell 11, for example arranged in an array. Cell 11 is a non-volatile memory cell.

Device 10 comprises a substrate, or support, 12. Support 12 is, for example, a stack of insulating layers 12a and 12b. For example, stack 12 comprises an alternation of layers 12a and 12b. Layers 12a are, for example, silicon oxide layers. Layers 12b are, for example, silicon nitride layers.

At least some of the layers of support 12 comprise copper conductive tracks 14. In particular, in the example of FIGS. 1A, 1B, and 1C, tracks 14 are located in the top layer of the support, that is, the layer closest to cell 11. The tracks 14 of said top layer are preferably located so at to be flush with the upper surface of the top layer of support 12.

Support 12, in particular the upper surface of the top layer of support 12, is for example covered with a stack 15 of insulating layers. Stack 15 comprises, in the example of FIGS. 1A, 1B, and 1C, an insulating layer 16 and an insulating layer 18. Layer 16 is for example made of silicon nitride. Layer 16 is, for example, made of the same material as layers 12b. Layer 18 is, for example, made of silicon oxide. Layer 18 is, for example, made of the same material as layers 12a.

Layer 16 is the lower layer of stack 15. Layer 18 is the upper layer of stack 15. Layer 16 is, for example, in contact with the upper surface of the top layer of support 12. Layer 18 is for example in contact with the upper surface of layer 16.

Stack 15 is crossed by at least one opening, or cavity, 20, preferably by a plurality of cavities 20. In the example of FIGS. 1A, 1B, and 1C, stack 15 comprises a plurality of parallel lines of cavities 20. Said lines of cavities 20 extend in the direction orthogonal to the cross-section plane of FIG. 1B. For example, stack 15 comprises groups 22 of lines of cavities 20. In the example of FIGS. 1A, 1B, and 1C, each group 22 comprises four lines of cavities 20. The lines of cavities 20 of a single group 22 are for example separated from each other by substantially the same distance. In other words, each line of a group 22 is separated from the neighboring lines of the same group by the same distance. The distances separating the lines of cavities 20 of a group 22 are, for example, substantially equal in all groups 22. All groups 22 are for example separated from each other by a same distance. The distance separating each group 22 is preferably greater than the distance separating the lines of a same group 22.

Each cavity 20 crosses stack 15, that is, in the example of FIGS. 1A, 1B, and 1C, layers 16 and 18. In other words, cavities 20 extend from the upper surface of layer 18 down to the lower surface of layer 16. Each cavity 20 extends so as to expose at least one track 14.

Each cavity 20 has, for example, a height corresponding to the sum of the thicknesses of layers 16 and 18, for example in the range from 0.5 to 1.5 μm, for example substantially equal to 1 μm. The horizontal dimensions of each cavity 20, that is, the dimensions in the plane of the upper surface of layer 18, are for example in the range from 50 nm to 150 nm, for example substantially equal to 100 nm.

Cell 11 comprises layers 24. Each layer 24 is located in a cavity 20. Each cavity 20 comprises a layer 24. There are thus preferably as many layers 24 as cavities 20.

Each layer 24 covers the side walls of the cavity 20 in which it is located, in other words, the walls of layers 16 and 18 located at the level of the cavity. Each layer 24 covers the portion of support 12 exposed by the cavity in which it is located. In other words, each layer 24 covers the portion of track 14 exposed by the cavity in which it is located, and possibly a portion of layer 12a in which track 14 is located. All the portions of tracks 14 exposed by cavities 20 are covered with a layer 24. Preferably, layer 24 does not extend outside of cavity 20. Thus, layer 24 preferably does not extend over the lower and upper walls of the layers of stack 15.

Each layer 24 is for example made of silicon-doped titanium nitride. Preferably, the silicon content in the material of each layer 24 is preferably lower than 20%, for example in the range from 10% to 20%.

The layers 24 of cell 11 are for example electrically coupled to one another by tracks 14 of support 12. Layers 24 form a first electrode of cell 11.

Cell 11 further comprises a layer 26. Layer 26 is a ferroelectric layer. Layer 26 is for example made of an oxide, for example of silicon-doped hafnium oxide (HfO2), for example with a silicon content in the range from 0.5% to 5%. As a variant, layer 26 may be made of HfZrO2. As a variant, layer 26 is for example a stack of ferroelectric layers.

Layer 26 covers, preferably entirely, layers 24. Layer 26 for example covers at least a portion of the upper surface of layer 18. Preferably, the portions of layer 26 located in cavities 20, that is, the portions covering layers 24, are coupled to one another by portions of layer 26 located on the upper surface of layer 18.

Cell 11 further comprises a conductive layer 28, for example made of metal. Layer 28 is preferably a continuous and entirely metallic layer. Layer 28 is for example made of titanium nitride, of tantalum nitride, or of doped polysilicon. Layer 28 forms the second electrode of cell 11. Layer 28 for example has a thickness strictly higher than 1 nm, for example higher than or equal to 3 nm, for example ranging from 3 nm to 20 nm.

Layer 28 covers, preferably entirely, layer 26. Layer 28 thus extends over the portions of layer 26 covering the walls of cavities 20, over the portions of layer 26 covering the exposed portions of tracks 14 and of stack 12, and over the portions of layer 26 covering the upper surface of layer 18. Preferably, layer 28 only covers layer 26. Thus, layer 28 is preferably not in contact with layer 18.

The device 10 further comprises a layer 30. Layer 30 is made of an insulating material, for example, of a nitride, for example, of a silicon nitride. Layer 30 covers, preferably entirely, layer 28. Layer 30 thus extends over the portions of layer 28 covering the walls of cavities 20, over the portions of layer 28 covering the exposed portions of tracks 14 and of stack 12, and over the portions of layer 28 covering the upper surface of layer 18. Preferably, layer 30 only covers layer 28. Thus, layer 30 is preferably not in contact with layer 18 or with layers 24.

Preferably, the portions 31 of layer 18 are not covered with layers 26, 28, 30. Portions 31 are preferably at least partially in front of tracks 14.

The device comprises a stack 38 of insulating layers 32, 34, and 36. Layer 32 forms the bottom layer of stack 38. Layer 36 forms the top layer of stack 38. Layer 34 forms an inner or intermediate layer of stack 38.

Layer 32 rests on layer 18, on cell 11, and on layer 30. In other words, at least a portion of layer 18 is covered by, preferably in contact with, the upper surface of layer 32. The upper surface of layer 30 is covered by, preferably in contact with, layer 32. Preferably, the upper surface of layer 30 is entirely covered by, preferably in contact with, layer 32. The side walls of the portions of layers 26, 28, 30 resting on the upper surface of layer 18 are covered, preferably in contact with layer 32.

Layer 34 rests on the upper surface of layer 32. Layer 34 is for example in contact with the upper surface of layer 32.

Layer 36 rests on the upper surface of layer 34. Layer 36 is for example in contact with the upper surface of layer 34.

Layer 32 is for example made of an oxide, for example of silicon oxide. Layer 34 is for example made of a nitride, for example of silicon nitride. Layer 36 is for example made of an oxide, for example of silicon oxide.

Device 10 comprises connection elements, or connection pads, 40. Elements 40 are for example made of metal, for example of copper. Elements 42 cross layers 16, 18, 32, 34, and 36 so as to reach tracks 14, preferably the tracks 14 located in the top layer of stack 12. Preferably, each element 42 is in contact with a portion of layer 28 located on the upper surface of layer 18, preferably between two groups of lines of cavities 20. Elements 40 are for example coupled together and to layers 24 by conductive tracks 14. Elements 40 are thus coupled to the first electrode of cell 11.

Device 10 comprises connection elements 42. Elements 42 are for example made of metal, for example of copper. Elements 42 are in contact with layer 28. More precisely, each element 42 crosses layers 30, 32, 34, and 36 to reach layer 28. Preferably, each element 42 is in contact with a portion of layer 28 located on the upper surface of layer 18, preferably between two groups of lines of cavities 20. Elements 42 are thus coupled to the second electrode of cell 11.

Elements 42 are for example coupled together by tracks 44. Tracks 44 are for example made of metal, for example of copper. Tracks 44 extend in layers 34 and 36. For example, tracks 44 extend from the lower surface of layer 34 to the upper layer of layer 36.

During the operation of device 10, cell 11 can be read by determining the electrical polarity of layer 26. The programming of cell 11 is thus performed by applying the desired polarity to layer 26, for example by applying an adapted voltage to the electrodes of the cell.

As a variant, the bottom of cavities 20 may be made of insulating material. The layer comprises, for example, portions extending over the upper surface of layer 18. The device may comprise connection elements, for example insulated conductive vias, reaching the portions of layer 24 extending over the upper surface of layer 18.

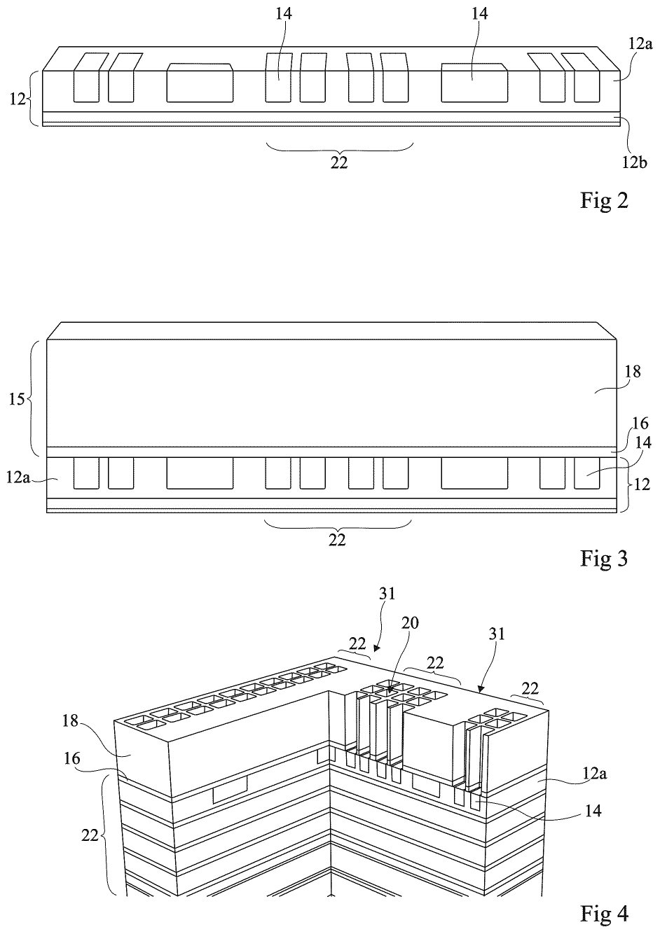

FIGS. 2 to 9 illustrate steps, preferably successive, of a method of manufacturing the embodiment of the device of FIGS. 1A, 1B, and 1C.

FIG. 2 shows a step of a method of manufacturing the embodiment of FIGS. 1A, 1B, and 1C.

During this step, stack 12 and tracks 14 are formed. In other words, layers 12a and 12b are formed one on top of the other to obtain an alternation of layers 12a and 12b. Preferably, the upper layer of stack 12 is a layer 12a.

Tracks 14 are formed in layers 12a. The tracks 14 of each layer 12a are for example formed during the forming of layer 12a.

FIG. 3 shows another step of a method of manufacturing the embodiment of FIGS. 1A, 1B, and 1C.

During this step, stack 15 is formed. In other words, layer 16 is formed on top of, preferably in contact with, the upper surface of the top layer 12a of stack 12 and on top of, preferably in contact with, the upper surfaces of tracks 14 flush with the upper surface of the top layer 12a of stack 12. Preferably, layer 16 is formed over the entire upper surface of the top layer 12a of stack 12 and over all the upper surfaces of tracks 14 flush with the upper surface of the top layer 12a of stack 12.

Further, layer 18 is formed on top of, preferably in contact with, layer 16. Preferably, layer 18 covers, preferably is in contact with, the entire layer 16, more precisely the entire upper surface of layer 16.

FIG. 4 shows another step of a method of manufacturing the embodiment of FIGS. 1A, 1B, and 1C.

During this step, cavities 20 are formed in layers 16 and 18. More precisely, the groups 22 of lines of cavities 20 are formed in layers 16 and 18. Each cavity 20 exposes a portion of a conductive track 14, preferably a conductive track 14 located in the top layer 12a of stack 12. Preferably, all the tracks 14 having portion exposed by cavities 20 are coupled together, for example by tracks 14 located in one or a plurality of layers of stack 12.

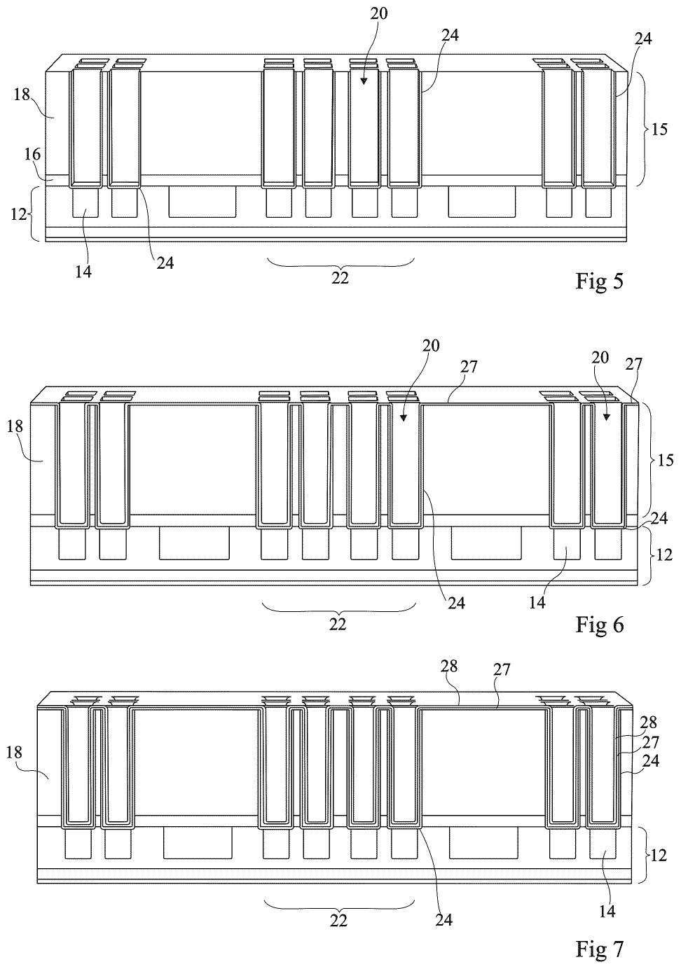

FIG. 5 shows another step of a method of manufacturing the embodiment of FIGS. 1A, 1B, and 1C.

During this step, layers 24 are formed. More precisely, a layer 24 is formed in each cavity 20.

For example, the forming of layers 24 comprises the forming of a layer, not shown, made of the material of layers 24. Said layer is formed so as to have a thickness substantially equal to the thickness of layers 24. Said layer is formed conformally on the structure resulting from the step of FIG. 4. Said layer covers the walls and the bottom of the cavities formed by cavities 20. In particular, the portion of a track 14 located at the bottom of the cavity is entirely covered by layer 24. Thus, tracks 14 are entirely covered by layer 18 or layers 24.

Layer 24 is preferably formed by a method of atomic layer deposition or ALD. Such a method enables to deposit layers having thicknesses of a few nanometers by the use of gas, which enables to form conformal layers entirely covering the exposed surfaces. In particular, it is thus possible to entirely cover the exposed portions of tracks 14. Further, such a method allows a good control of the dopant concentration and may be used in method of back-end type. The portions of said layer located outside of cavities 20 are then removed.

FIG. 6 shows another step of a method of manufacturing the embodiment of FIGS. 1A, 1B, and 1C.

During this step, a layer 27 is formed. More precisely, layer 27 is formed conformally over the entire structure resulting from the step of FIG. 5. Layer 27 covers layers 24. In other words, layer 27 extends over the walls and the bottom of the cavity formed by each cavity 20. Layer 27 further extends over the upper surface of layer 18.

Layer 27 is made of a dielectric material which can be made ferroelectric by an anneal step. Layer 27 is for example made of silicon-doped hafnium oxide (HfO2), for example with a silicon content in the range from 0.5% to 5%. Layer 27 may alternatively be made of HfZrO2.

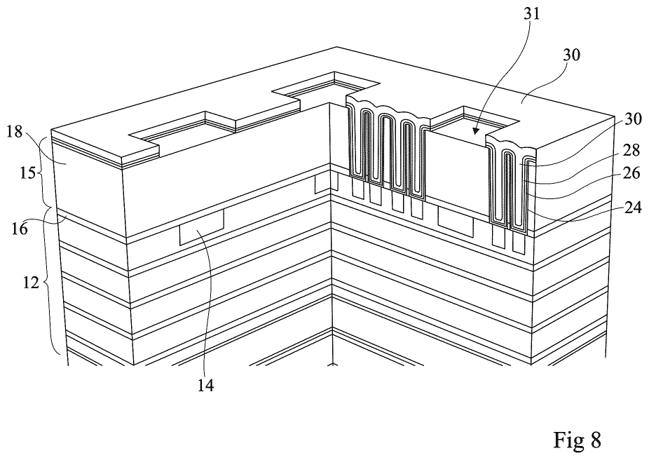

FIG. 7 shows another step of a method of manufacturing the embodiment of FIGS. 1A, 1B, and 1C.

During this step, layer 28 is formed. More precisely, layer 28 is formed conformally over the entire structure resulting from the step of FIG. 6. Layer 28 covers layer 27. Thus, layer 28 extends over the walls and the bottom of the cavity formed by each cavity, as well as the upper surface of layer 18. In particular, layer 28 entirely covers the portion of layer 27 corresponding to the layer 26 of cell 11.

FIG. 8 shows another step of a method of manufacturing the embodiment of FIGS. 1A, 1B, and 1C.

During this step, layer 30 is formed over the entire structure resulting from step 7. Layer 30 is, for example, sufficiently thick to fill cavities 20.

The step of FIG. 8 also comprises a step of anneal of the structure forming layer 26. More precisely, the step of FIG. 8 comprises the annealing of the portions of layer 27 corresponding to the layer 26 of cell 11. The anneal step enables to make the portions of layer 27 corresponding to the layer 26 of cell 11 ferroelectric.

The anneal step is carried out by the application of a laser to the entire structure, in particular to the portion of layer 27 corresponding to layers 26. The wavelength of the laser, the material of layer 28, and the thickness of layer 28 are selected so that layer 28 absorbs the laser and heats, particularly by diffusion, the layer 27 located in contact with the portions of layer 28 having absorbed the laser. Preferably, the laser is fully absorbed by layer 28. Preferably, layer 27 is heated to a local temperature higher than 400° C., for example higher than 500° C.

The wavelength of the laser is, for example, shorter than 1,100 nm, for example, shorter than 400 nm, for example shorter than 360 nm, for example equal to 308 nm. For example, for a wavelength equal to 308 nm, a titanium nitride layer 28 having a thickness in the range from 20 nm to 30 nm enables to fully absorb the laser and to make the portions of layer 27 corresponding to layer 26 ferroelectric.

According to an embodiment, the laser is configured to have known dimensions and shape, and to only reach the location of cell 11, that is, the portions of layer 28 located in contact with the portions of layer 27 corresponding to layer 26.

According to another embodiment, the laser is configured to have dimensions enabling to reach the location of cell 11 and at least a portion of the structure surrounding the location of the cell. For example, the laser is configured to be applied to the entire device. The anneal step then comprises the forming of a protection mask covering at least said portion, for example the entire device, so that the laser is reflected on the mask and only reaches the location of the cell.

The material of layer 30 is configured to be transparent to the wavelength of the laser. The layer is, for example, silicon nitride.

Preferably, the laser is applied to the structure in the form of short pulses, so as not to heat and not to damage the metals of the structure, in particular the material of layer 24. The pulses have for example a duration shorter than 1 μs, for example, shorter than 200 ns, for example shorter than 100 ns.

The power of the pulses and their duration depend, for example, on the dimensions of cavities 20. For example, cavities 20 have a height smaller than 600 nm, and dimensions in the plane of the upper surface of layer 18 smaller than 170 nm, for example smaller than 100 nm. If cavities 20 have larger dimensions, the power of the laser enabling to make the entire layer 26 ferroelectric would cause damage to the rest of the structure.

The stack of layers 26, 28, and 30 is then etched at locations 31. In other words, a portion of the stack of layers 26, 28, and 30 is etched between each group 22 of lines of cavities 20. Thus, at locations 31, layers 26, 28, and 30 are etched to expose layer 18.

The portions of layer 30 located in front of or in the cavities are not etched.

Each of locations 31 is located in front of a track 14. Said tracks 14 are preferably coupled together. Said tracks 14 are preferably not coupled to the tracks 14 being in contact with layers 24.

The method of manufacturing the embodiment of FIG. 1 comprises steps subsequent to the step of FIG. 8. During these steps, the stack 38 of insulating layers is formed on the structure resulting from the step of FIG. 8 and connection elements 40, 42, and 44 are formed.

As a variant, the anneal step may be carried out between the step of forming of layer 28 and the step of forming of layer 30.

More generally, the anneal step is carried out while layer 28 entirely covers the structure, that is, before a step of etching of layer 28, to protect the underlying structures from the laser, in particular the copper structures, for example tracks 14. Thus, the steps of FIGS. 7 and 8 may comprise, in this order, either the forming of layer 28, the forming of layer 30 and the anneal, or the forming of layer 28, the anneal, and the forming of layer 30.

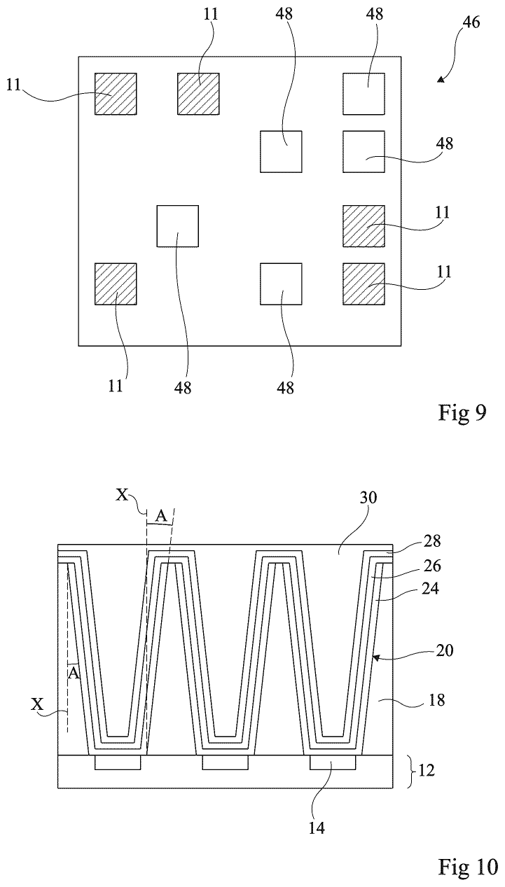

FIG. 9 shows schematically a top view of a device 46 comprising cells 11 such as described in relation with FIGS. 1A, 1B, and 1C.

More specifically, device 46 comprises non-volatile memory cells 11 and volatile memory cells 48.

Capacitors 48 are metal-oxide-metal (MOM) capacitors. Capacitors 48 are each formed of layers 24, 26, 28, which layer 26 has not been submitted to the anneal step at the location of capacitor 48.

More specifically, the method of manufacturing device 46 comprises the steps of FIGS. 2 to 8, the anneal step being carried out so that only the locations of cells 11 are submitted to the anneal step. Capacitors 48 are obtained by the steps of FIGS. 2 to 8 except for the anneal step. Capacitors 48 and cells 11 are for example formed simultaneously, the steps in FIGS. 2 to 8 other than anneal being carried out simultaneously for at least part of cells 11 and of capacitors 48, preferably for all cells 11 and all capacitors 48.

Capacitors 48 and cells 11 are for example located in a same level, for example in the same stack 15.

At least some of capacitors 48 and at least some of cells 11 are, for example, located in a same region. Thus, a capacitor 48 may be located between two cells 11 and a cell 11 may be located between two capacitors 48.

FIG. 10 shows another embodiment of an electronic device. More precisely, FIG. 10 shows a portion of a cell 11 according to a variant. FIG. 10 shows a cross-section view of a cell 11.

Cell 11 differs from the cell 11 of FIGS. 1A to 1C in that, unlike the cell of FIGS. 1A to 1C, the side walls of the cavities 20 of cell 11 are not vertical, that is, are not perpendicular to a horizontal axis, that is, are not perpendicular to the plane of the upper surface of support 12.

The side walls of the cavities 20 of the cell 11 of FIG. 10 are inclined. More precisely, the side walls of cavities 20 are inclined outwards. In other words, the surface area of the opening of the cavity is greater than the surface area of the bottom of the cavity. Preferably, all the walls of each cavity 20 are inclined. Each side wall forms with a vertical X axis, that is, an X axis orthogonal to the plane of the upper surface of support 12, an angle A. Angle A is preferably in the range from 0.5° to 10°, for example in the range from 0.5° to 5°.

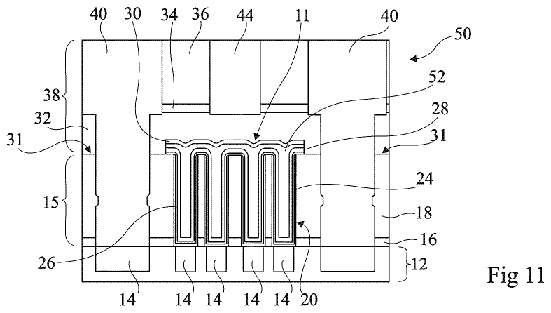

FIG. 11 shows another embodiment of an electronic device 50. More specifically, FIG. 11 shows a cross-section view of an embodiment of device 50 along the same plane as FIG. 1B.

Device 50 comprises the elements of the device 10 of FIGS. 1A to 1C. Thus, device 50 comprises:
support 12, having conductive tracks 14 located therein;
insulating layers 16 and 18;
cavities 20;
layers 24, 26, 28, located in cavities 20;
insulating layers 30, 32, 34, 36;
conductive elements 40; and
conductive tracks 44.

Device 50 differs from device 10 in that device 50 comprises a layer 52 between layer 28 and layer 30. Layer 52 is a conductive layer, for example made of metal, for example made of tungsten. Layer 52 is for example made of a different material than layer 28.

Layer 52 covers, preferably entirely, layer 28. Layer 52 thus extends over the portions of layer 28 covering the walls of cavities 20, over the portions of layer 28 covering the exposed portions of tracks 14 and of stack 12, and over the portions of layer 28 covering the upper surface of layer 18. Layer 52 for example fills cavities 20. Preferably, layer 52 only covers layer 28. Thus, layer 52 is preferably not in contact with layer 18 or with layers 24.

Device 50 comprises, like the device 10 of FIGS. 1A to 1C, layer 30. The layer 30 of device 50 differs from the layer 30 of device 10 in that layer 30 covers layer 52. Thus, layer 30 is for example not located in cavities 20. Layer 30 thus rests on layer 52, preferably only on layer 52. Layer 30 is thus separated from layer 28 by layer 52. As in FIGS. 1A to 1C, layer 30 is preferably not in contact with layers 24, 26, 28 or with layer 18.

The method of manufacturing device 50 differs from the method of manufacturing device 10 in that the method further comprises the forming of layer 52 between the forming of layer 28 and the forming of layer 30. Layers 28, 52, and 30 are for example etched during the same etch step.

The anneal step, for example corresponding to the step of FIG. 6, is for example carried out after the deposition of layer 28, after the deposition of layers 52 and 28, or after the deposition of layer 30.

The embodiment of FIG. 11 may for example be combined with the embodiment of FIG. 10. Thus, the walls of the cavities 20 of device 50 may be inclined, as described in relation with FIG. 10.

An advantage of the described embodiments is that it is possible to form ferroelectric non-volatile memory cells.

Another advantage of the described embodiments is that it is possible to simultaneously form memory cells and capacitors.

Another advantage of the described embodiments is that the forming of the cells comprises a single additional step as compared with the forming of capacitors.

An advantage of the embodiment of FIG. 11 is that the laser more easily reaches, during the anneal step, the portions of layer 27 extending over the side walls of cavity 20. The power of the laser can thus be lower than the power used in the case where the walls are vertical. There is thus less risk of damaging the structure.

An advantage of the embodiment of FIG. 11 is that it enables to heat, and thus to make ferroelectric, layer 27, or layer 26 more homogeneously, due to an improved heat conduction by the layer 52 which fills cavity 20.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. Method of manufacturing an electronic device, the method comprising:
the forming of a support comprising at least a first insulating layer having conductive tracks located therein;
the forming of a second insulating layer on the support;
the forming of cavities in the second insulating layer; and
the forming of a memory cell in a first location comprising:
the forming of a stack of layers, the stack extending over the walls and the bottom of the cavities, the stack comprising a layer made of material capable of becoming ferroelectric located between a first conductive layer and a second conductive layer, the forming of the stack comprising the forming of the first and second conductive layers and of a dielectric layer between the first and second conductive layers;
the application of a laser to the stack of layers at at least the first location so as to activate ferroelectric properties of the layer made of a material capable of becoming ferroelectric;
the forming of a layer covering the second conductive layer, said layer being:
a protective layer covering the second conductive layer, the step of application of the laser being carried out after the forming of the protective layer; or
a third conductive layer covering the second conductive layer, the third conductive layer filling the cavities.

2. Method according to claim 1, wherein the laser is only applied to the first location.

3. Method according to claim 1, wherein the laser is applied to the entire device, portions of the second conductive layer surrounding the first location being protected, during the application of the laser, by a protection mask.

4. Method according to claim 1, wherein, during the application of the laser, the dielectric layer is entirely covered by the second conductive layer.

5. Method according to claim 1, wherein the protective layer is transparent to the wavelength of the laser.

6. Method according to claim 1, wherein the second conductive layer has a thickness strictly higher than 1 nm, for example higher than or equal to 3 nm, for example ranging from 3 nm to 20 nm, the second layer being made of a material authorizing the full absorption of the energy of the laser so as to heat the dielectric layer by diffusion.

7. Method according to claim 6, wherein the dielectric layer is heated to a temperature higher than 500° C.

8. Method according to claim 1, wherein the laser is applied in pulses having a duration shorter than 1 μs.

9. Method according to claim 1, wherein the laser has a wavelength shorter than 400 nm.

10. Method according to claim 1, wherein the method comprises the manufacturing of at least one capacitor in a second location, the capacitor comprising the first and second conductive layers and the dielectric layer, and the laser is not applied to the dielectric layer at the second location.

11. Method according to claim 1, wherein the side walls of the cavities are inclined and each form an angle in the range from 0.5° to 5° with a direction orthogonal to the plane of the bottom of the cavities.

12. Method according to claim 1, wherein the layer made of a ferroelectric material is made of hafnium oxide or of HfZrO2.

13. Method according to claim 1, wherein the layer made of a ferroelectric material is made of silicon-doped hafnium oxide, the silicon content being in the range from 0.5% to 5%.

14. Method according to claim 1, wherein the first conductive layer is made of silicon doped titanium nitride.

15. Electronic device comprising:
a support comprising at least a first insulating layer having conductive tracks located therein and a second insulating layer comprising cavities;
a memory cell comprising a stack of layers, the stack extending over the walls and the bottom of the cavities, the stack comprising a layer made of ferroelectric material located between a first conductive layer and a second conductive layer, the second conductive layer being continuous and entirely metallic;
a layer covering the second conductive layer, said layer being:
a protective layer; or
a third conductive layer, the third conductive layer filling the cavities.

16. Device according to claim 15, the device comprising a capacitor comprising a stack of layers, the stack extending over the walls and the bottom of the cavities, the stack comprising a layer made of material capable of becoming ferroelectric located between a first conductive layer and a second conductive layer, the second conductive layer being continuous and entirely metallic.
